(19) United States
(12) Patent Application Publication
(10) Pub. No.: US 2021/0389428 A1
(43) Pub. Date: Dec. 16, 2021

(54) LIGHT EMITTING DEVICE FOR LIDAR

(71) Applicant: DELTA ELECTRONICS, INC., Taoyuan City (TW)

(72) Inventor: Gow-Zin YIU, Taoyuan City (TW)

(21) Appl. No.: 17/169,516

(22) Filed: Feb. 7, 2021

(30) Foreign Application Priority Data
Jun. 11, 2020 (CN) 202010528374.6

(51) Int. Cl. G01S 7/481; G01S 7/484

(52) U.S. Cl. CPC G01S 7/4815; G01S 7/484; G01S 7/4817

(57) ABSTRACT

A light emitting device for lidar includes a transistor, a laser light source, and an energy-storage capacitor. The transistor is embedded inside a substrate. The laser light source is disposed on the substrate and electrically connected to the transistor. The energy-storage capacitor is disposed on the substrate and electrically connected to the laser light source. The transistor is selectively turned on in response to a gate controlling signal so as to discharge the energy-storage capacitor, such that the laser light source emits a light pulse. The transistor is disposed opposite to the laser light source.

### RELATED APPLICATIONS

This application claims priority to Chinese Application Serial Number 202010528374.6, filed Jun. 11, 2020, the disclosures of which are incorporated herein by reference in their entireties.

### BACKGROUND

### Field of Invention

The present invention relates to a light emitting device for lidar. More particularly, the present invention relates to a modular packaging assembly which is a light emitting device for lidar.

### Description of Related Art

Light Detection And Ranging (lidar) is an important component of self-driving cars. Lidar can be used for obstacle detection, preceding car following, lane keeping, etc. Lidar uses light to measure a distance to a target. A pulse laser light is emitted toward the target. A propagation time of the pulse laser light from being emitted to being reflected by the target and returning to the light source is measured. Then, the traveling speed of the pulse laser light can be obtained, such that the distance to the target can be calculated.

Because lidar needs to generate a pulse laser light with an extremely high energy in an extremely short time, the light source of lidar emitted the pulse laser light needs a large current in an extremely short time to be passed through, and therefore a series resistance of the conduction path needs to be extremely low and the conduction path needs to be extremely short. However, the requirement for the low series resistance will be limited by the design layout limitation of the copper traces on the printed circuit board. Furthermore, the limitation of the layout of the printed circuit board will cause the parasitic resistance and the parasitic inductance between the components to become very large, thereby limiting the pulse width and the intensity of the pulse laser light. In addition, the large current switching generated in an extremely short time when the light source of the lidar is turned on and off will not only cause interference to other peripheral circuits but also cause serious ground bounce.

### SUMMARY

The present invention provides a light emitting device for lidar. The light emitting device for lidar includes a transistor, a laser light source, and an energy-storage capacitor. The transistor is embedded inside a substrate. The laser light source is disposed on the substrate and electrically connected to the transistor. The energy-storage capacitor is disposed on the substrate and electrically connected to the laser light source. The transistor is selectively turned on in response to a gate controlling signal so as to discharge the energy-storage capacitor, such that the laser light source emits a light pulse. The transistor is disposed opposite to the laser light source.

In accordance with one or more embodiments of the invention, the light emitting device for lidar further includes a gate driver disposed on the substrate and electrically connected to a gate electrode of the transistor. The gate driver is configured to generate the gate controlling signal in response to a pulse trigger signal.

In accordance with one or more embodiments of the invention, the light emitting device for lidar further includes a charging resistance disposed on the substrate. The charging resistance is electrically connected between a bias voltage source and the energy-storage capacitor, such that the bias voltage source charges the energy-storage capacitor toward a bias voltage of the bias voltage source through the charging resistance.

In accordance with one or more embodiments of the invention, the transistor is a silicon carbide (SiC) field-effect transistor (FET).

In accordance with one or more embodiments of the invention, the laser light source is a laser diode (LD) or a vertical-cavity surface-emitting laser (VCSEL).

In accordance with one or more embodiments of the invention, a cathode terminal of the laser light source is electrically connected to a drain electrode of the transistor through a conductive pillar.

In accordance with one or more embodiments of the invention, one end of the conductive pillar is connected to a surface of the cathode terminal of the laser light source, and the other end of the conductive pillar is connected to the drain electrode of the transistor.

In accordance with one or more embodiments of the invention, the energy-storage capacitor is electrically connected to an anode terminal of the laser light source through a bonding wire.

In accordance with one or more embodiments of the invention, the gate driver is electrically connected to the gate electrode of the transistor through a conductive pillar.

In accordance with one or more embodiments of the invention, the substrate is an organic substrate or a printed circuit board (PCB).

In accordance with one or more embodiments of the invention, the light emitting device is a packaging device or an integrated module.

In accordance with one or more embodiments of the invention, the transistor is embedded inside the substrate by using an embedded electronic packaging technology.

### BRIEF DESCRIPTION OF THE DRAWINGS

The invention can be more fully understood by reading the following detailed description of the embodiment, with reference made to the accompanying drawings as follows:

FIG. 1 illustrates a cross-sectional view of a light emitting device for lidar according to some embodiments of the present invention.

FIG. 2 illustrates a circuit diagram of the light emitting device for lidar according to some embodiments of the present invention.

### DETAILED DESCRIPTION

Specific embodiments of the present invention are further described in detail below with reference to the accompanying drawings, however, the embodiments described are not intended to limit the present invention and it is not intended for the description of operation to limit the order of implementation. Moreover, any device with equivalent functions that is produced from a structure formed by a recombination of elements shall fall within the scope of the present invention. Additionally, the drawings are only illustrative and are not drawn to actual size.

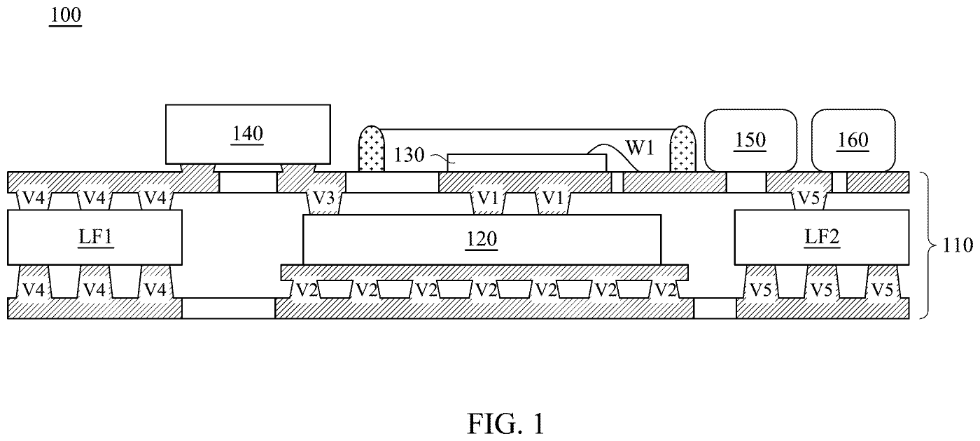

FIG. 1 illustrates a cross-sectional view of a light emitting device 100 for lidar according to some embodiments of the present invention. The light emitting device 100 includes a substrate 110, a transistor 120, a laser light source 130, a gate driver 140, an energy-storage capacitor 150, and a charging resistance 160. In some embodiments of the present invention, the substrate 110 is an organic substrate or a printed circuit board (PCB). In some embodiments of the present invention, the transistor 120 is embedded inside the substrate 110 by using an embedded electronic packaging technology.

The laser light source 130, the gate driver 140, the energy-storage capacitor 150, and the charging resistance 160 are respectively disposed (populated) on a top surface of the substrate 110. The transistor 120 is disposed opposite to the laser light source 130. Furthermore, the transistor 120 is disposed inside the substrate 110. The transistor 120 is preferably lower than the top surface of the substrate 110. The laser light source 130 is disposed above the transistor 120. There is a conductive pillar V1 disposed between the transistor 120 and the laser light source 130. The transistor 120 is electrically connected to the laser light source 130 through the conductive pillar V1. And, the laser light source 130 is preferably disposed directly above the transistor 120, that is, the light source 130 and the transistor 120 partially overlap in a vertical projection direction. In some embodiments of the present invention, the laser light source 130 is a laser diode (LD) or a vertical-cavity surface-emitting laser (VCSEL), and the laser light source 130 is configured to emit a light pulse.

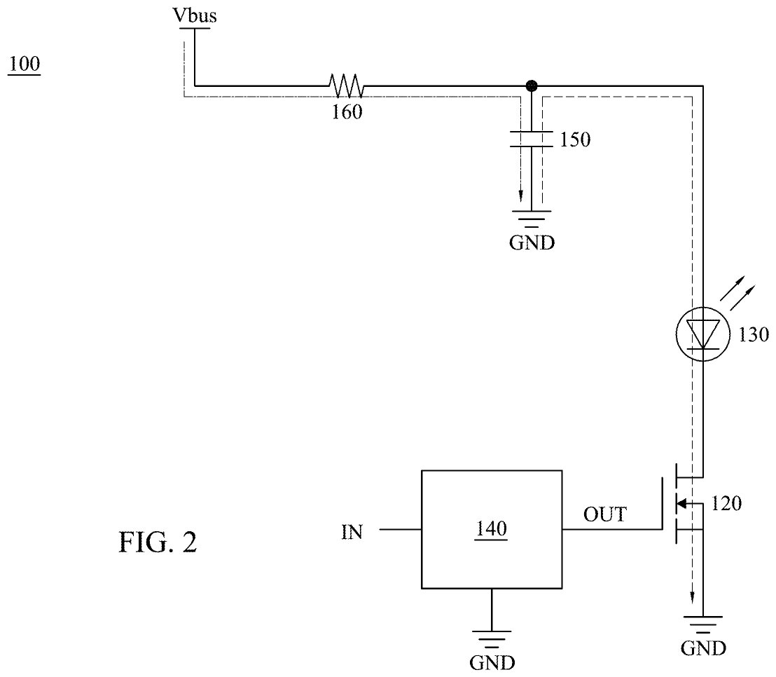

FIG. 2 illustrates a circuit diagram of the light emitting device 100 for lidar according to some embodiments of the present invention. FIG. 2 is used for better explaining the connection relationship between the components of the light emitting device 100. Referring to FIG. 1 and FIG. 2, in some embodiments of the present invention, a surface of a cathode terminal of the laser light source 130 is connected to one end of the conductive pillar V1, and a drain electrode of the transistor 120 is connected to the other end of the conductive pillar V1. In other words, the cathode terminal of the laser light source 130 is electrically connected to the drain electrode of the transistor 120 embedded inside the substrate 110 through the conductive pillar V1. And, a source electrode of the transistor 120 is electrically connected to a ground plane GND through a conductive pillar V2.

In some embodiments of the present invention, a first terminal (i.e., an output terminal/a control terminal) of the gate driver 140 is electrically connected to a gate electrode of the transistor 120 through a conductive pillar V3. A second terminal (i.e., an input terminal) of the gate driver 140 is configured to receive a pulse trigger signal IN. A third terminal (i.e., a ground terminal) of the gate driver 140 is electrically connected to the ground plane GND through a conductive pillar V4 and a lead frame LF1.

The gate driver 140 may be a gate driving circuit composed of logic gates and transistors. The gate driver 140 is configured to generate a gate controlling signal OUT in response to the pulse trigger signal IN, thereby selectively turning on the transistor 120. In other words, the gate driver 140 is a gate driver connected to the gate electrode of the transistor 120. The gate driver 140 is configured to output the gate controlling signal OUT to the gate electrode of the transistor 120, such that the transistor 120 is turned on or off in accordance with the gate controlling signal OUT.

In some embodiments of the present invention, an anode terminal of the laser light source 130 is electrically connected to one end of the energy-storage capacitor 150 and one end of the charging resistance 160 through a bonding wire W1. The other end of the energy-storage capacitor 150 is electrically connected to the ground plane GND through a conductive pillar V5 and a lead frame LF2. The other end of the charging resistance 160 is electrically connected to a bias voltage source Vbus. In some embodiments of the present invention, a bias voltage of the bias voltage source Vbus is, for example, 0-75 volt.

When the transistor 120 is turned off, the bias voltage source Vbus charges the energy-storage capacitor 150 toward the bias voltage of the bias voltage source Vbus through the charging resistance 160 (as indicated by dotted line in FIG. 2). When the transistor 120 is turned on, the energy-storage capacitor 150, the laser light source 130, the transistor 120, and the ground plane GND form a series conduction path (as indicated by dashed line in FIG. 2). And, the energy-storage capacitor 150 is discharged through the aforementioned series conduction path, such that the laser light source 130 emits a light pulse.

In some embodiments of the present invention, the transistor 120 is a gallium nitride (GaN) field-effect transistor (FET). The on-resistance of GaN FET is extremely low (e.g., about 7 mOhm), and therefore a series resistance of the series conduction path is extremely low when the transistor 120 is turned on. In some other embodiments of the present invention, the transistor 120 is a silicon carbide (SiC) field-effect transistor (FET). The on-resistance of SiC FET is also extremely low, and therefore a series resistance of the series conduction path is extremely low when the transistor 120 is turned on. In some embodiments of the present invention, the transistor 120 is turned on in an extremely short time through the gate driver 140, and therefore the light emitting device 100 may correspondingly generate an extremely large current (e.g., about 100 amperes (A)) to pass through the laser light source 130 in an extremely short time (e.g., about 10 nanoseconds (ns)), such that the laser light source 130 may emit a light pulse that meets the requirements of the laser light source of lidar.

In some embodiments of the present invention, the transistor 120 is embedded inside the substrate 110, and the laser light source 130, the gate driver 140, the energy-storage capacitor 150, and the charging resistance 160 are respectively disposed (populated) on the substrate 110. In some embodiments of the present invention, the laser light source 130 is formed by a self-packaging method so as to form a modularized package structure. In other words, the light emitting device 100 is a packaging device or an integrated module.

In some embodiments of the present invention, the transistor 120 is embedded inside the substrate 110, and therefore a trace length from the transistor 120 embedded inside the substrate 110 to the laser light source 130 and the gate driver 140 disposed (populated) on the top surface of the substrate 110 may be shortened from a millimeter (mm) level to about 100 micrometers (μm). In addition, a trace length from the transistor 120 and the energy-storage capacitor 150 to the ground plane GND is also shortened to about a micrometer level. In other words, because the transistor 120 is embedded inside the substrate 110, the trace lengths of the light emitting device 100 may be greatly shortened, such that a parasitic resistance and a parasitic inductance of the series conduction path is greatly reduced when the transistor 120 is turned on so as to avoid the influence of the parasitic resistance and the parasitic inductance on signal transmission, thereby increasing the discharging speed. Therefore, a short and strong light pulse can be generated so as to meet the requirements of the laser light source of lidar.

In some embodiments of the present invention, when the energy-storage capacitor 150 is charged, a charging speed of the energy-storage capacitor 150 is adjusted by adjusting the resistance value of the charging resistance 160, such that the discharging speed of the energy-storage capacitor 150 is fast but the charging speed of the energy-storage capacitor 150 is extremely slow relative to the discharging speed of the energy-storage capacitor 150. Specifically, the charging speed of the energy-storage capacitor 150 is extremely slow, and therefore the light emitting device 100 of the present invention can improve electromagnetic interference (EMI) to other peripheral circuits, in which the aforementioned EMI is generated due to the large current switching when the laser light source of the lidar is turned on and off. And, the light emitting device 100 of the present invention can improve the ground bounce phenomenon.

From the above description, the present invention provides a light emitting device for lidar. The GaN FET or the SiC FET is embedded inside the substrate so as to form a modularized package structure. The light emitting device for lidar of the present invention may reduce the value of parasitic resistance and the value of the parasitic inductance to extremely low. And, each component of the light emitting device for lidar of the present invention is integrated in the package structure, and thus the property of the light emitting device for lidar of the present invention can be enhanced, and the interference to other peripheral circuits can be also reduced.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting device for lidar, comprising:
a transistor embedded inside a substrate;
a laser light source disposed on the substrate and electrically connected to the transistor; and
an energy-storage capacitor disposed on the substrate and electrically connected to the laser light source;
wherein the transistor is selectively turned on in response to a gate controlling signal so as to discharge the energy-storage capacitor, such that the laser light source emits a light pulse;
wherein the transistor is disposed opposite to the laser light source.

2. The light emitting device for lidar of claim 1, further comprising:
a gate driver disposed on the substrate and electrically connected to a gate electrode of the transistor, wherein the gate driver is configured to generate the gate controlling signal in response to a pulse trigger signal.

3. The light emitting device for lidar of claim 1, further comprising:
a charging resistance disposed on the substrate, wherein the charging resistance is electrically connected between a bias voltage source and the energy-storage capacitor, such that the bias voltage source charges the energy-storage capacitor toward a bias voltage of the bias voltage source through the charging resistance.

4. The light emitting device for lidar of claim 1, wherein the transistor is a silicon carbide (SiC) field-effect transistor (FET).

5. The light emitting device for lidar of claim 1, wherein the laser light source is a laser diode (LD) or a vertical-cavity surface-emitting laser (VCSEL).

6. The light emitting device for lidar of claim 1, wherein a cathode terminal of the laser light source is electrically connected to a drain electrode of the transistor through a conductive pillar.

7. The light emitting device for lidar of claim 6, wherein one end of the conductive pillar is connected to a surface of the cathode terminal of the laser light source, and the other end of the conductive pillar is connected to the drain electrode of the transistor.

8. The light emitting device for lidar of claim 1, wherein the energy-storage capacitor is electrically connected to an anode terminal of the laser light source through a bonding wire.

9. The light emitting device for lidar of claim 1, wherein the gate driver is electrically connected to the gate electrode of the transistor through a conductive pillar.

10. The light emitting device for lidar of claim 1, wherein the substrate is an organic substrate or a printed circuit board (PCB).

11. The light emitting device for lidar of claim 1, wherein the light emitting device is a packaging device or an integrated module.

12. The light emitting device for lidar of claim 1, wherein the transistor is embedded inside the substrate by using an embedded electronic packaging technology.
